(19) United States
(12) Patent Application Publication
(10) Pub. No.: US 2009/0202925 A1
(43) Pub. Date: Aug. 13, 2009

(54) PHOTOMASK DEFECT CORRECTION METHOD, PHOTOMASK MANUFACTURING METHOD, PHASE SHIFT MASK MANUFACTURING METHOD, PHOTOMASK, PHASE SHIFT MASK, PHOTOMASK SET, AND PATTERN TRANSFER METHOD

(75) Inventor: Hideki Suda, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: HOYA CORPORATION, Tokyo (JP)

(21) Appl. No.: 12/363,536

(22) Filed: Jan. 30, 2009

(30) Foreign Application Priority Data
Jan. 31, 2008 (JP) 2008-020379

(51) Int. Cl. G03F 1/00; G03F 9/00

(52) U.S. Cl. 430/5; 430/22

(57) ABSTRACT

A first photomask 1 has a first transfer pattern to be transferred onto an object and is adapted to be used in combination with a second photomask having a second transfer pattern to be transferred onto the object. Among pattern defects 4 and 5 generated in the first transfer pattern, defect correction is performed only for the pattern defect 4 which is to be transferred onto the object within a region out of an area where a pattern corresponding to the first transfer pattern is not formed on the object as a result of transferring the second transfer pattern.

This application is based upon and claims the benefit of priority from Japanese patent application No. 2008-020379, filed on Jan. 31, 2008, the disclosure of which is incorporated herein in its entirety by reference.

### TECHNICAL FIELD

This invention relates to a method of manufacturing a photomask for use in transferring a fine pattern, such as an LSI pattern, by the use of a projection exposure apparatus and, in particular, to a method of easily performing defect correction of a photomask, a phase shift mask manufacturing method, a phase shift mask, a photomask set, and a pattern transfer method.

### BACKGROUND ART

With higher integration and circuit pattern miniaturization in large-scale integrated circuits (LSIs), phase shift masks have been proposed as one of super-resolution techniques and put into practical use in the photolithography. The phase shift masks are often used in manufacture of semiconductor devices having fine patterns because of the advantage in resolution performance and depth of focus.

Various types of phase shift masks have been proposed, such as a Levenson type, an edge emphasizing type, an auxiliary pattern type, a chromeless type, and a halftone type.

Among the phase shift masks, the alternating phase shift technique (alternating phase shift mask (alternating PSM) or Levenson-type phase shift mask) is useful for a line-and-space pattern in which an aperture pattern is regularly repeated. In the phase shift mask of the type, the resolution performance can be improved by giving a phase difference of substantially 180° between lights transmitted through adjacent light-transmitting portions. As a layer for giving the phase difference (phase shifter), a trench formed by etching a quartz substrate or of a phase shift film adapted to transmit exposure light may be used.

For example, the Levenson-type phase shift mask has a light-shielding pattern of, for instance, metal film such as chromium film formed on a transparent substrate. The Levenson-type phase shift mask is configured so that, in the case where light-shielding portions and light-transmitting portions are alternately arranged, for example, in the case of a line-and-space pattern, the phases of transmitted lights transmitted through the light-transmitting portions adjacent to each other with the light-shielding portion interposed therebetween are shifted or offset by 180° from each other. Because of the shift in phase between the transmitted lights transmitted through the light-transmitting portions adjacent to each other, a reduction in resolution due to interference between diffracted lights can be prevented to thereby achieve an improvement in resolution of the line-and-space pattern.

In the above-mentioned phase shift mask, between the light-transmitting portions adjacent to each other via the light-shielding portion, an optical path length difference of [λ(2m−1)/2] (where m is a natural number) is provided with respect to the transmitted lights having a wavelength λ. As a consequence, the phase difference of 180° is produced between the transmitted lights. In order to provide the above-mentioned optical path length difference, a difference d in thickness of the transparent substrate between the light-transmitting portions adjacent to each other via the light-shielding portion should satisfy [d=λ(2m−1)/2n] where n represents a refractive index of the transparent substrate.

In the phase shift mask, in order to provide the difference in thickness of the transparent substrate between the light-transmitting portions, the transparent substrate is coated with a transparent thin film at one of these light-transmitting portions to thereby increase the thickness. Alternatively, the transparent substrate is dug down at one of these light-transmitting portions to thereby reduce the thickness. Thus, in a shifter-coated type (convex type) phase shift mask in which the transparent substrate is coated with the transparent thin film, the transparent substrate is covered with the transparent thin film (shifter) having a thickness d (=λ(2m−1)/2n) at a phase shift portion. On the other hand, in a trench type phase shift mask in which the transparent substrate is dug down, the transparent substrate is etched by a depth d (=λ(2m−1)/2n) at a phase shift portion. Another light-transmitting portion, which is neither coated with the transparent thin film nor dug down, serves as a phase-unshifted portion. In the case where the light-transmitting portions have a shallow trench and a deep trench, the shallow trench serves as a phase-unshifted portion.

When the above-mentioned phase shift mask is used, it may be necessary to perform exposure twice at the same position of a photoresist layer on an object. Basically, second exposure is carried out in order to erase an unwanted pattern generated by first exposure or to provide an additional pattern to a pattern formed by the first exposure.

Japanese Unexamined Patent Application Publication (JP-A) No. H11-260699 (Patent Document 1) discloses a pattern forming method for transferring a gate pattern onto a positive resist by performing exposure a plurality of times. In the technique described in Patent Document 1, using a photomask with a mask pattern having light-shielding portions corresponding to a device region and a gate pattern forming region and another photomask with a mask pattern having light-transmitting portions corresponding to the device region except the gate pattern forming region, double exposure is performed under exposure conditions optimal for the respective photomasks to thereby form a resist pattern. Thus, Patent Document 1 discloses that a transfer pattern formed by a phase shift mask is partly erased by a second mask.

### SUMMARY OF THE INVENTION

For example, it is assumed that a line-and-space pattern is transferred onto a positive resist film formed on an object by using a Levenson-type phase shift mask. In this event, at terminal end of lines by a phase shifter, unwanted lines are formed due to unintended phase boundaries. In order to erase such unwanted lines, it is proposed to carry out second exposure (trim exposure) by the use of a trim mask.

In the meantime, also in phase shift masks, it is impossible to completely avoid the occurrence of pattern shape defects during fabrication, like in other masks. These defects include a missing defect of a light-shielding film formed on a transparent substrate, an opaque defect formed on the transparent substrate, a phase defect such as phase shifter missing or phase shifter misalignment caused in a phase shift region, and so on. Such defects are corrected when correction is possible. When correction is impossible, the mask as a whole is unusable.

The tolerance range for those defects is limited by the performance of a device to be obtained by using a mask. Generally, the defect tolerance range is determined depending on use of a mask and as a specification for a single kind of mask. That is, with respect to a single kind of mask, there was no situation where different defect specifications are given depending on regions thereof. Therefore, basically, any defects on a phase shift mask pattern should be inspected and corrected so as to satisfy a given specification.

On the other hand, circuits of semiconductor devices presently formed by the photolithography tend to be more and more miniaturized and, consequently, the range of allowable defects is minimized also. In the situation where it is impossible to completely avoid the occurrence of defects in phase shift masks, defect inspection and correction processes impede the production efficiency. Accordingly, an improvement of the yield in these processes is desired more than ever.

Under the above-mentioned circumstances, it is an object of this invention to provide a defect correction method for a phase shift mask, which is capable of improving the efficiency of defect inspection and correction processes for the phase shift mask to thereby improve and stabilize the yield in mask production. It is another object of this invention to provide a method of manufacturing a phase shift mask, which includes the defect correction method mentioned above. It is still another object of this invention to provide a phase shift mask manufactured through a correction process according to the above-mentioned defect correction method. It is yet another object of this invention to provide a photomask set including the above-mentioned phase shift mask.

For the purpose of furthermore obtaining a resolution as well as the depth of focus brought by the application of a phase shift mask, the present inventors have studied the techniques of multiple exposure (patterns are successively transferred onto the same object by using a plurality of photomasks, thereby resolving a fine pattern that cannot be resolved by a single photomask) and multiple patterning (patterning is successively carried on the same object using a plurality of photomasks, thereby obtaining the patterning accuracy higher than that obtained by a single photolithography process using a single photomask). Through the study, the present inventors have recognized that, in these techniques also, there is a demand for a defect correction method with high efficiency and high yield. Therefore, it is also an object of this invention to meet such a demand.

In order to achieve the above-mentioned objects, this invention has any one of the following structures.

[Structure 1]

A defect correction method for a photomask, the photomask having a first transfer pattern to be transferred onto an object, the photomask being adapted to be used in combination with an additional photomask having a second transfer pattern to be transferred onto the object, wherein:

a pattern defect which is produced in the first transfer pattern is corrected only if the pattern defect is to be transferred onto the object within a region which is out of an area where a pattern corresponding to the first transfer pattern is not formed on the object as a result of transferring the second transfer pattern onto the object.

[Structure 2]

The defect correction method according to Structure 1, wherein the first transfer pattern includes a phase shift pattern having a trench formed on a transparent substrate.

[Structure 3]

The defect correction method according to Structure 1 or 2, wherein one of the first and the second transfer patterns is adapted to erase an unwanted pattern formed on the object by the other of the first and the second transfer patterns.

[Structure 4]

The defect correction method according to any one of Structures 1 though 3, wherein the first and the second transfer patterns are designed so that transferring one of the first and the second transfer patterns onto the object increases an apparent resolution when the other of the first and the second transfer patterns is transferred onto the object.

[Structure 5]

A photomask manufacturing method comprising a defect correction process according to the defect correction method according to any one of Structures 1 to 4.

[Structure 6]

A method of manufacturing a phase shift mask comprising a transparent substrate on which a light-shielding layer and a shifter layer each subjected to predetermined patterning are formed so that the phase shift mask has a phase shift mask pattern including a phase-unshifted light-transmitting portion, a phase shift portion, and a light-shielding portion, the phase shift portion being adapted to transmit exposure light with a phase shift of substantially 180° relative to unshifted exposure light transmitted through the phase-unshifted light-transmitting portion, the method comprising a defect correction process of performing defect correction of the phase shift mask pattern formed after the patterning of the light-shielding layer and the shifter layer, the defect correction process including identifying a position of a pattern defect in the phase shift mask pattern, referring to data of a trim mask pattern formed on a trim mask to be transferred onto an object before or after the phase shift mask pattern is transferred onto the object using the phase shift mask, and correcting the position-identified pattern defect only if the pattern defect is to be transferred onto the object within a region which is out of an area where a pattern corresponding to the phase shift mask pattern is not formed on the object as a result of transferring the trim mask pattern onto the object.

[Structure 7]

A photomask having a first transfer pattern to be transferred onto an object, the photomask being adapted to be used in combination with an additional photomask having a second transfer pattern to be transferred onto the object, wherein a pattern defect which is produced in the first transfer pattern is corrected only if the pattern defect is to be transferred onto the object within a region which is out of an area where a pattern corresponding to the first transfer pattern is not formed on the object as a result of transferring the second transfer pattern onto the object.

[Structure 8]

A phase shift mask having a phase shift mask pattern to be transferred onto an object and including a phase shift portion, the phase shift mask being adapted to be used in combination with a second mask having a second transfer pattern to be transferred onto the object, wherein a pattern defect which is produced in the phase shift mask pattern is corrected only if the pattern defect is to be transferred onto the object within a region which is out of an area where a pattern corresponding to the phase shift pattern is not formed on the object as a result of transferring the second transfer pattern onto the object using the second mask.

[Structure 9]

A photomask set comprising a phase shift mask and a trim mask, the phase shift mask having a phase shift mask pattern to be transferred onto an object and including a phase shift portion, the trim mask having a trim mask pattern to be transferred onto the object before or after the phase shift mask pattern is transferred onto the object using the phase shift mask, wherein the phase shift mask is subjected to defect correction only for a region except a trim region, the trim region being an area contained within a range of the phase shift mask pattern and overlapping a light-transmitting portion of the trim mask pattern when the phase shift mask pattern and the trim mask pattern are superposed on each other.

[Structure 10]

A pattern transfer method comprising transferring a pattern onto an object using a photomask manufactured by the method according to Structure 5, a phase shift mask manufactured by the method according to Structure 6, a photomask according to Structure 7, or a phase shift mask according to Structure 8.

In a defect correction method for a photomask according to Structure 1 of this invention, defect correction is performed on a photomask having a first transfer pattern to be transferred onto an object. The photomask is adapted to be used in combination with an additional photomask having a second transfer pattern to be transferred onto the object. A pattern defect which is produced in the first transfer pattern is corrected only if the pattern defect is to be transferred onto the object within a region which is out of an area where a pattern corresponding to the first transfer pattern is not formed on the object as a result of transferring the second transfer pattern onto the object. Therefore, it is possible to minimize a workload for defect correction and thus to achieve efficient production. Herein, the pattern corresponding to the first transfer pattern is not formed on the object as a result of transferring the second transfer pattern onto the object because, for example, the pattern corresponding to the first transfer pattern is superposed and erased as a result of transferring the second transfer pattern onto the object.

In the defect correction method according to Structure 2 of this invention, the first transfer pattern may be a phase shift pattern having a trench formed on a transparent substrate.

In the defect correction method according to Structure 3 of this invention, one of the first and the second transfer patterns is adapted to erase an unwanted pattern formed on the object by the other of the first and the second transfer patterns. Therefore, it is possible to minimize a workload for defect correction and thus to achieve efficient production.

In the defect correction method according Structure 4 of this invention, the first and the second transfer patterns are designed so that transferring one of the first and the second transfer patterns onto the object increases an apparent resolution when the other of the first and the second transfer patterns is transferred onto the object. Therefore, it is possible to manufacture a photomask with high resolution.

The photomask manufacturing method according to Structure 5 of this invention includes a defect correction process according to the defect correction method according to any one of Structures 1 to 4. Therefore, it is possible to minimize a workload for defect correction and thus to efficiently manufacture photomasks.

In the phase shift mask manufacturing method according Structure 6 of this invention, the defect correction process includes identifying a position of a pattern defect in the phase shift mask pattern, referring to data of a trim mask pattern formed on a trim mask to be transferred onto an object before or after the phase shift mask pattern is transferred onto the object using the phase shift mask, and correcting the position-identified pattern defect only if the pattern defect is to be transferred onto the object within a region which is out of an area where a pattern corresponding to the phase shift mask pattern is not formed on the object as a result of transferring the trim mask pattern onto the object. Therefore, it is possible to minimize a workload for defect correction and thus to achieve efficient production. That is, in the phase shift mask manufacturing method according to this invention, it is possible to manufacture phase shift masks efficiently without requiring a complicated process, in conformity with an intended use, and, as a result, stably with high yield.

The photomask according to Structure 7 of this invention has a first transfer pattern to be transferred onto an object. The photomask is adapted to be used in combination with an additional photomask having a second transfer pattern to be transferred onto the object. A pattern defect which is produced in the first transfer pattern is corrected only if the pattern defect is to be transferred onto the object within a region which is out of an area where a pattern corresponding to the first transfer pattern is not formed on the object as a result of transferring the second transfer pattern onto the object. Therefore, it is possible to minimize a workload for defect correction thus to achieve efficient production.

The phase shift mask according to Structure 8 of this invention has a phase shift mask pattern to be transferred onto an object. The phase shift mask is adapted to be used in combination with a second mask having a second transfer pattern to be transferred onto the object. A pattern defect which is produced in the phase shift mask pattern is corrected only if the pattern defect is to be transferred onto the object within a region which is out of an area where a pattern corresponding to the phase shift pattern is not formed on the object as a result of transferring the second transfer pattern onto the object using the second mask. Therefore, it is possible to minimize a workload for defect correction and thus to achieve efficient production.

The photomask set according to Structure 9 of this invention comprises a phase shift mask and a trim mask. The phase shift mask has a phase shift mask pattern to be transferred onto an object and including a phase shift portion. The trim mask has a trim mask pattern to be transferred onto the object before or after the phase shift mask pattern is transferred onto the object using the phase shift mask. The phase shift mask is subjected to defect correction only for a region except a trim region. The trim region is an area contained within a range of the phase shift mask pattern and overlapping a light-transmitting portion of the trim mask pattern when the phase shift mask pattern and the trim mask pattern are superposed on each other. Therefore, it is possible to minimize a workload for defect correction and thus to achieve efficient production.

In the pattern transfer method according to Structure 10 of this invention, a pattern is transferred onto an object using a photomask manufactured by the photomask manufacturing method according to Structure 5, a phase shift mask manufactured by the phase shift mask manufacturing method according to Structure 6, a photomask according to Structure 7, or a phase shift mask according to Structure 8. Thus, by using the photomask or the phase shift mask efficiently manufactured with the minimized workload for defect correction, it is possible to efficiently perform pattern transfer.

As described above, this invention provides a photomask defect correction method, a photomask manufacturing method, and a phase shift mask manufacturing method which are capable of improving the efficiency of defect inspection and correction processes for a photomask to thereby improve and stabilize the yield in mask production. This invention also provides a photomask, a phase shift mask, and a photomask set manufactured through the correction process according to the above-mentioned methods. Further, this invention provides a pattern transfer method using the photomask or the phase shift mask mentioned above.

### BRIEF DESCRIPTION OF THE DRAWINGS

FIGS. 1A to 1D are plan views illustrating the structures of a phase shift mask and a trim mask to which a phase shift mask manufacturing method according to this invention is applicable;

FIGS. 2A and 2B are plan views illustrating the structures of a Levenson-type phase shift mask and a trim mask in the case where a positive resist is used for fabricating the phase shift mask and a negative resist is used for fabricating the trim mask;

FIGS. 3A and 3B are plan views illustrating the structures of a Levenson-type phase shift mask and a trim mask in the case where a negative resist is used for fabricating the phase shift mask and a positive resist is used for fabricating the trim mask;

FIGS. 4A and 4B are plan views illustrating the structures of a Levenson-type phase shift mask and a trim mask in the case where a negative resist is used for fabricating the phase shift mask and a positive resist is used for fabricating the trim mask;

FIG. 5 is a plan view illustrating various kinds of defects generated in the phase shift mask shown in FIG. 2A;

FIG. 6 is a plan view illustrating various kinds of defects generated in the phase shift mask shown in FIG. 4A;

FIGS. 7A to 7H are schematic sectional views for describing a manufacturing process of a Levenson-type phase shift mask 1 according to an example of this invention;

FIGS. 8A to 8C are schematic sectional views for describing a manufacturing process of a trim mask;

FIGS. 9A to 9E are plan views illustrating parts of patterns formed on photomasks and a wafer;

FIGS. 10A to 10H are views for describing a patterning process by double exposure;

FIGS. 11A, 11B and 11C are a top view of a first mask, a top view of a second mask, and a top view of a resist on a wafer after transfer, respectively;

FIGS. 12A and 12B are views illustrating defects of the first and the second masks in an example, respectively;

FIGS. 13A to 13L are views for describing a patterning process by double patterning;

FIGS. 14A, 14B and 14C are a top view of a first mask, a top view of a second mask, and a top view of a resist on a wafer after transfer, respectively;

FIGS. 15A and 15B are views illustrating defects of the first and the second masks in an example, respectively;

FIGS. 16A to 16D are schematic sectional views for describing a manufacturing process of the first mask; and

FIGS. 17A to 17G are schematic sectional views for describing a manufacturing process of the second mask.

### DESCRIPTION OF THE EXEMPLARY EMBODIMENTS

Now, referring to the drawing, description will be made in detail of a photomask manufacturing method according to exemplary embodiments of this invention. The photomask manufacturing method includes, as one process, a photomask defect correction method according to this invention. It will be understood that this invention is not limited to the following description. For example, a transparent substrate may be any desired one of various substrates as long as the effect of this invention is not impaired. A light-shielding layer may be any one of various coating layers.

In this invention, first and second transfer patterns are used in combination so as to form a desired device pattern on the same object. Herein, the object may be a thin film to be processed using a mask or the thin film with a resist film formed thereon.

For example, the first and the second transfer patterns are transferred onto the same object by successive exposure so as to provide the resist film of the object with a predetermined optical pattern, thereby forming on the resist film a latent image of a desired device pattern.

Alternatively, the first and the second transfer patterns may be as follows: First, one of the transfer patterns is transferred by exposure onto the resist film of the object. Then, the resist film is developed, thereby forming a first resist pattern. Using the first resist pattern as a mask, the thin film of the object is etched, thereby forming a first thin film pattern. Thereafter, the resist is stripped. Onto a new resist film formed on the thin film pattern, the other transfer pattern is transferred by exposure. Then, in the manner similar to that mentioned above, the new resist film is developed and the thin film is etched, thereby forming a second thin film pattern. As a result, a desired device pattern is formed on the thin film.

A third transfer pattern may be used in addition to the first and the second transfer patterns.

Herein, depending on the intended use and the performance of a device to be obtained, the above-mentioned thin film may be a thin film of a metal or the like which has a suitable thickness.

The first transfer pattern may be a phase shift mask pattern including a phase shift portion. The second transfer pattern may be designed so as to prevent formation of an unwanted pattern (including the case of erasing the unwanted pattern) which would be formed on the object when only the first transfer pattern is transferred onto the object. A trim mask is known as a mask which prevents formation of a pattern to be formed in a certain region on the object by the first transfer pattern.

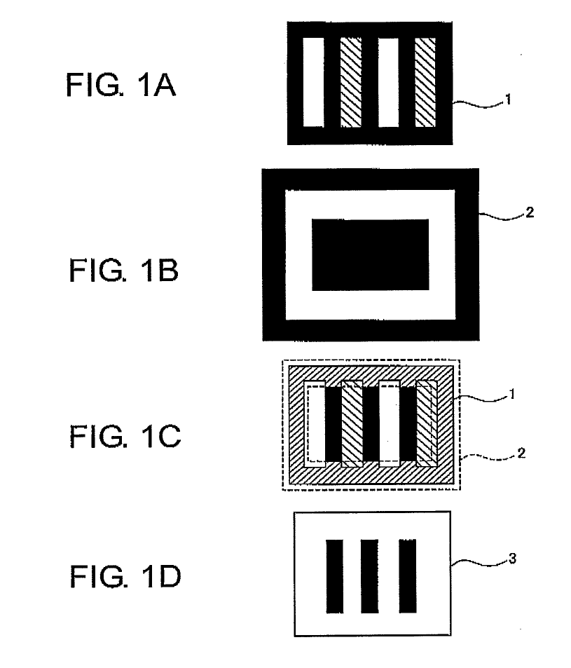

FIGS. 1A to 1D are plan views showing the structures of a phase shift mask (first photomask) and a trim mask (second photomask) to which a phase shift mask manufacturing method according to this invention is applicable.

It is assumed that a line-and-space pattern with three lines (as a part of a desired device pattern) is formed on a wafer 3 as shown in FIG. 1D using a phase shift mask according to this invention. In this event, a Levenson-type phase shift mask 1 is first fabricated as shown in FIG. 1A. Using the phase shift mask 1, a positive resist film formed on the wafer 3 is exposed. In FIG. 1A, a black portion is a light-shielding portion of Cr, a white portion is a phase-unshifted portion (light-transmitting portion) where a transparent substrate is exposed. A hatched portion is a trench formed by digging down the substrate by an amount such that exposure light transmitted therethrough is inverted in phase by 180° relative to unshifted exposure light transmitted through the phase-unshifted portion or a phase shift portion protruded by a level such that the phase inversion of 180° is given. In the light-shielding portion and the phase shift portion, a layer (lower layer) adjacent to the transparent substrate may be a surface layer portion of the transparent substrate.

Then, a trim mask 2 is fabricated as shown in FIG. 1B. Using the trim mask 2, exposure is performed on the same positive resist film as shown in FIG. 1C, thereby obtaining the desired line-and-space pattern with three lines. As shown in FIG. 1D, on the wafer 3, pattern outer edge lines formed by the exposure using the phase shift mask 1 are erased by the exposure (trim exposure) using the trim mask 2.

It is noted here that either the exposure using the phase shift mask 1 or the exposure using the trim mask 2 may be carried out first.

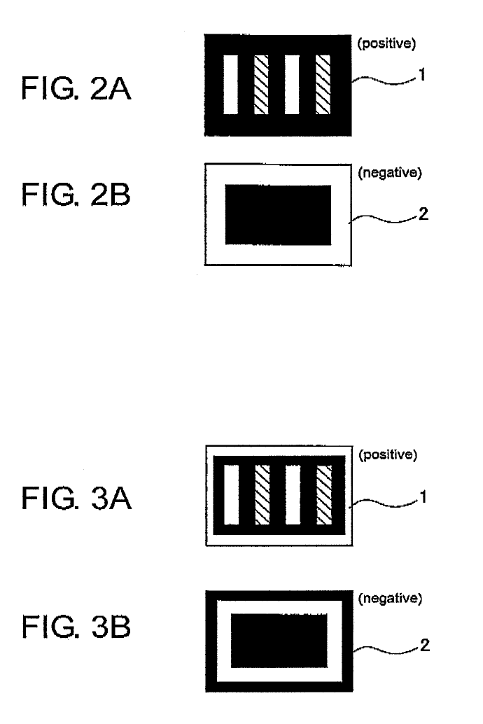

In mask fabrication, several combinations in structure are conceived as a combination of the Levenson-type phase shift mask 1 and the trim mask 2. FIGS. 2A to 4B illustrate examples of masks in different combinations which are used in the case where a line-and-space pattern with three lines is formed on the wafer 3 in the manner similar to that described above.

FIGS. 2A and 2B are plan views illustrating the structures of a Levenson-type phase shift mask 1 and a trim mask 2 in the case where a positive resist is used for fabricating the phase shift mask and a negative resist is used for fabricating the trim mask.

FIGS. 3A and 3B are plan views illustrating the structures of a Levenson-type phase shift mask 1 and a trim mask 2 in the case where a negative resist is used for fabricating the phase shift mask and a positive resist is used for fabricating the trim mask.

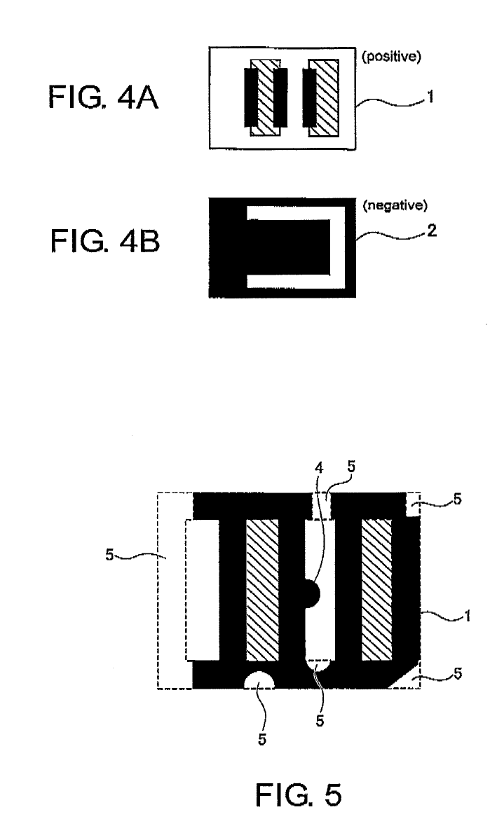

FIGS. 4A and 4B are plan views illustrating the structures of a Levenson-type phase shift mask 1 and a trim mask 2 in the case where a negative resist is used for fabricating the phase shift mask and a positive resist is used for fabricating the trim mask.

The phase shift mask 1 shown in FIG. 4A has a structure in which edges of phase shift portions are exposed. Also in this case, unwanted patterns due to the shifter edges can be erased by exposure using the trim mask 2.

In pattern formation on the object by the above-mentioned combinations of the Levenson-type phase shift mask 1 and the trim mask 2, it is possible, by applying the defect correction method according to this invention, to improve the efficiency of defect inspection and defect correction and thus to achieve an improvement in yield, as is different from typical mask fabrication methods.

According to this invention, in the defect correction process for the phase shift mask 1, defect correction is not performed for a region where the pattern is finally erased as a result of exposure using the trim mask 2, but is performed only for the other region except the above-mentioned region.

FIG. 5 is a plan view illustrating various kinds of defects generated in the phase shift mask 1 shown in FIG. 2A.

As shown in FIG. 5, it is assumed that various kinds of defects 4 and 5 are generated in the phase shift mask 1 shown in FIG. 2A. In this case, it is hitherto judged that the mask requires correction or is rejected as a defective product because a pattern is not formed in conformity with a design. However, taken into account that exposure using the trim mask 2 shown in FIG. 2B is carried out, it is understood that, among various kinds of the defects 4 and 5, only the residual defect 4 located in a device pattern portion (region at a center portion) has an influence upon a wafer. Therefore, in this case, only the residual defect 4 located in the main pattern portion should be corrected. The defect correction may be performed by cutting or abrading the transparent substrate by using laser light irradiation, FIB, or the like.

Herein, the device pattern portion is a pattern portion involved in the structure of an electronic device to be actually obtained, i.e. a pattern portion that should be transferred onto the object. According to this invention, a region of a mask pattern where no defect correction is performed is a trim region where a pattern formed on the object by the phase shift pattern, accurately, an undeveloped latent image formed on the resist, is erased by exposure using the trim mask 2. Preferably, the region where no defect correction is performed is the trim region except a margin area of a predetermined width from a peripheral edge of the trim region. The margin area may be determined depending on the shape of the mask pattern, the wavelength of exposure light used for a mask, and so on.

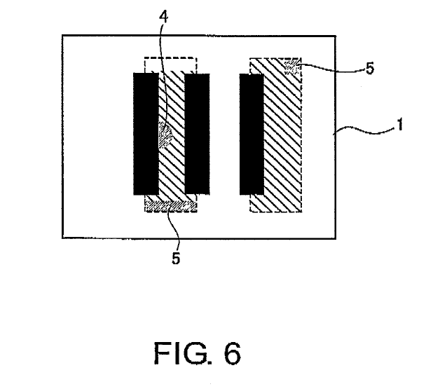

FIG. 6 is a plan view illustrating various kinds of defects generated in the phase shift mask 1 shown in FIG. 4A.

As shown in FIG. 6, it is assumed that various kinds of phase shifter defects 4 and 5 are generated in the phase shift mask 1 shown in FIG. 4A. In this case, it is hitherto judged that the mask requires correction or is rejected as a defective product because a pattern is not formed in conformity with a design. However, taken into account that exposure using the trim mask 2 shown in FIG. 4B is carried out, it is understood that, among various kinds of the defects 4 and 5, only the residual defect 4 located in a device pattern portion (region at a center portion) has an influence upon a wafer. Therefore, in this case, only the residual defect 4 located in the device pattern portion should be corrected.

Heretofore, a phase shift mask having fatal defects is rejected as a defective mask unless those defects are corrected. On the other hand, in the phase shift mask manufacturing method according to this invention, those defects are classified into a defect which must be corrected and a defect which need not be corrected, taking into account the exposure using a trim mask. The phase shift mask can be used as a good product without defect correction for the defect which need not be corrected.

Thus, even if a defect is generated in a mask pattern of a first photomask, presence or absence of the defect may have no influence upon a pattern finally formed on the object when pattern transfer on the same object is performed using both of the first photomask and another mask (second photomask) in combination. In this case, in the mask correction process, the above-mentioned defect is not corrected but the other defects are corrected.

Therefore, in this invention, the favorable effect can be obtained in production efficiency and yield of the phase shift mask.

According to this invention, in the defect correction process, a position of each pattern defect in a phase shift mask pattern of the phase shift mask 1 is identified. Referring to data of a trim mask pattern of the trim mask 2, the position-identified pattern defect is classified into a defect to be corrected and a defect which need not be corrected.

Specifically, the position-identified pattern defect is corrected only if the pattern defect is to be transferred onto the object within a region except an area (trim region) where a pattern corresponding to the phase shift mask pattern is not formed on the object as a result of exposure (first exposure) using the phase shift mask 1 and exposure (second exposure) using the trim mask 2. Thus, it is possible to minimize a workload for defect correction and thus to achieve the efficient production. Either the first exposure or the second exposure may be carried out first.

Thus, the phase shift mask according to this invention is manufactured by correcting the pattern defect generated in the phase shift mask pattern 1 only if the pattern defect is to be transferred onto the object within a region which is out of an area where a pattern corresponding to the phase shift mask pattern is not formed on the object as a result of transfer to the object by exposure using the phase shift mask 1 and transfer to the object by exposure using the trim mask 2.

A photomask set according to this invention comprises a combination of the phase shift mask 1 according to this invention and manufactured as mentioned above and the trim mask 2.

As described above, this invention provides a defect correction method for a phase shift mask and a method of manufacturing a phase shift mask which are capable of improving the efficiency of defect inspection and correction processes for a phase shift mask to thereby improve and stabilize the yield in mask production. This invention further provides a phase shift mask and a photomask set manufactured through such correction process.

It will readily be understood that this invention is not limited to a combination of a phase shift mask and a trim mask.

For example, first and second transfer patterns are successively transferred onto a resist film of the same object by exposure under different exposure conditions (for example, lighting methods). In this manner, it is possible to form a fine resist pattern of a high resolution that cannot be achieved only by a single transfer pattern. In such a case, a part of the first transfer pattern may be erased by transfer of the second transfer pattern by exposure. In this case, defect correction should be performed only for a region except an area where the first transfer pattern is erased by transfer of the second transfer pattern by exposure.

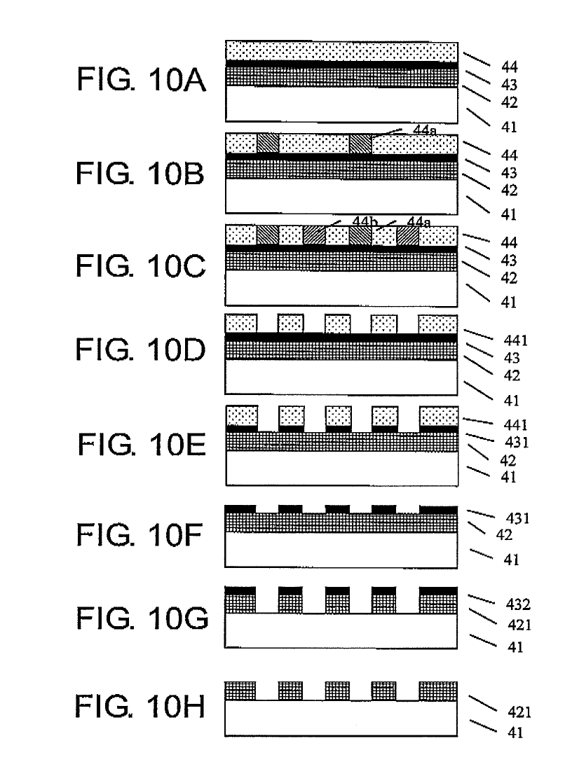

A typical process for fine pattern formation by double exposure will be described later with reference to FIGS. 10A to 10H.

Besides the above-mentioned example where multiple exposure is performed on the resist film of the same object, a processed film (film to be processed by etching) of the same object may be subjected to a plurality of times of patterning to thereby form a device pattern with higher working accuracy. In such a case, for example, defect correction of the first transfer pattern should be performed only for a region excluding an area where a pattern formed by first transfer (patterning) is erased by second transfer (patterning).

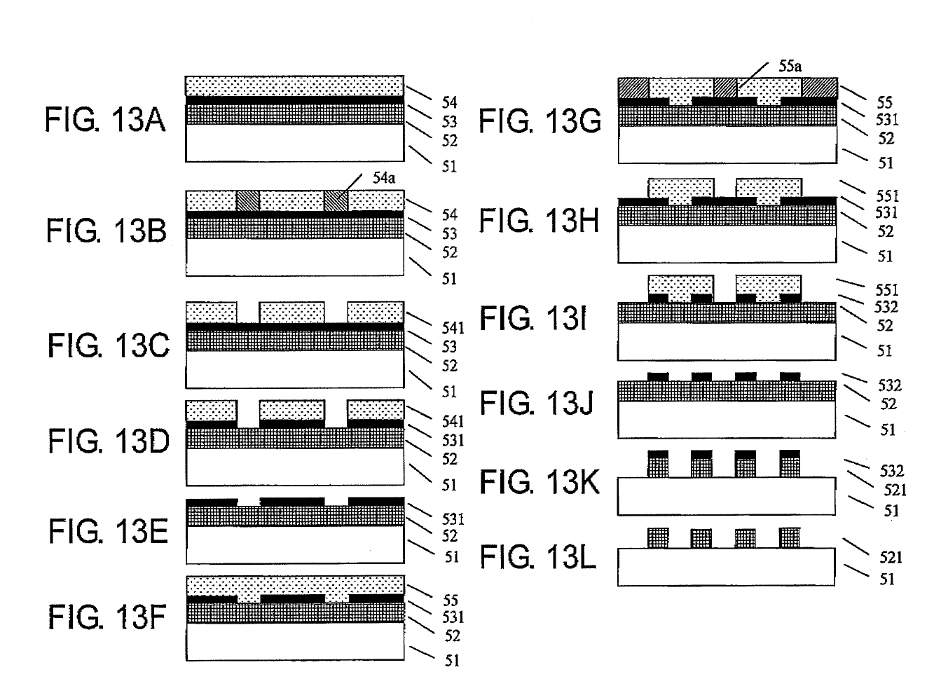

A typical process for fine pattern formation by double patterning will be described later with reference to FIGS. 13A to 13L.

### Example 1

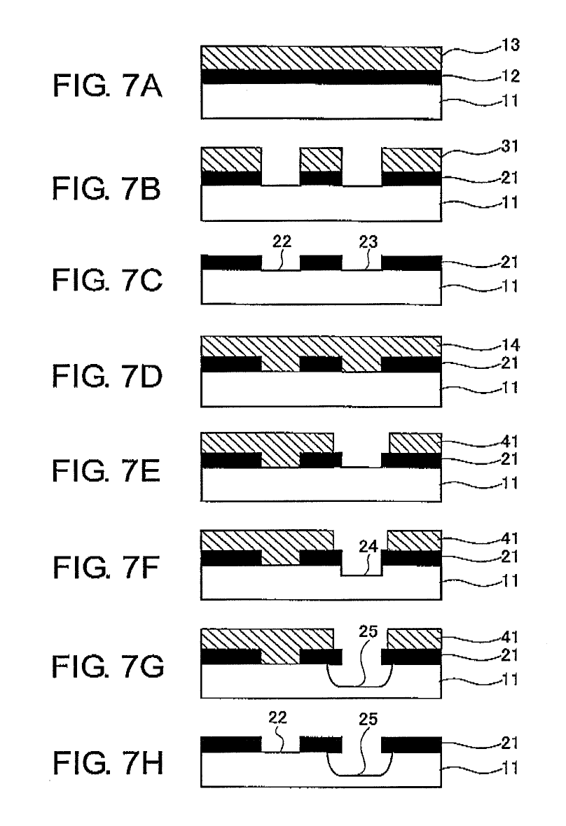

FIGS. 7A to 7H are schematic sectional views illustrating a manufacturing process of a Levenson-type phase shift mask 1 according to an example of this invention. Hereinbelow, the example of this invention will be described with reference to FIGS. 7A to 7H.

As a transparent substrate 11 of the phase shift mask 1, use was made of a quartz glass substrate (having a size of 6 inch square and a thickness of 0.25 inch) having mirror-polished surfaces and subjected to predetermined cleaning. At first, as shown in FIG. 7A, a light-shielding film 12 of chromium was deposited on the transparent substrate 11 to a thickness of 100 nm by sputtering. Then, a positive-type electron-beam resist (“ZEP7000” manufactured by Zeon Corporation) 13 was applied to a thickness of 500 nm by spin coating.

Next, as shown in FIG. 7B, in order to form a light-transmitting portion, a desired pattern was drawn by electron-beam writing and then developed, thereby forming a resist pattern 31. Then, using the resist pattern 31 as a mask, the light-shielding film 12 was dry-etched with a mixed gas of Cl₂ and O₂, thereby obtaining a light-shielding film pattern 21 having designed dimensions.

Then, as shown in FIG. 7C, the resist was stripped, thereby forming a first-stage mask having the light-shielding film pattern 21.

Next, as shown in FIG. 7D, a positive-type electron-beam resist (“ZEP7000” manufactured by Zeon Corporation) 14 was applied in order to form a light-transmitting portion having a shifter.

Then, as shown in FIG. 7E, in order to form the light-transmitting portion having the shifter, a desired pattern was drawn by electron-beam writing and then developed, thereby forming a resist pattern 41.

Subsequently, as shown in FIG. 7F, using the resist pattern 41 as a mask, the substrate was dry-etched to a depth of 100 nm with a mixed gas of CF₄ and O₂, thereby obtaining a phase shift light-transmitting portion 24. Herein, since ArF exposure is assumed, the etching amount of the quartz glass substrate is 170 nm in order to obtain a phase difference of 180° and the side-etching amount from the Cr edge is supposed to be 70 nm.

Subsequently, as shown in FIG. 7G, similarly using the resist pattern 41 as a mask, wet etching was continuously performed by 70 nm with buffered hydrofluoric acid, thereby obtaining a shifter pattern 25.

Finally, as shown in FIG. 7H, the resist was stripped, thereby completing a mask patterned to the final stage.

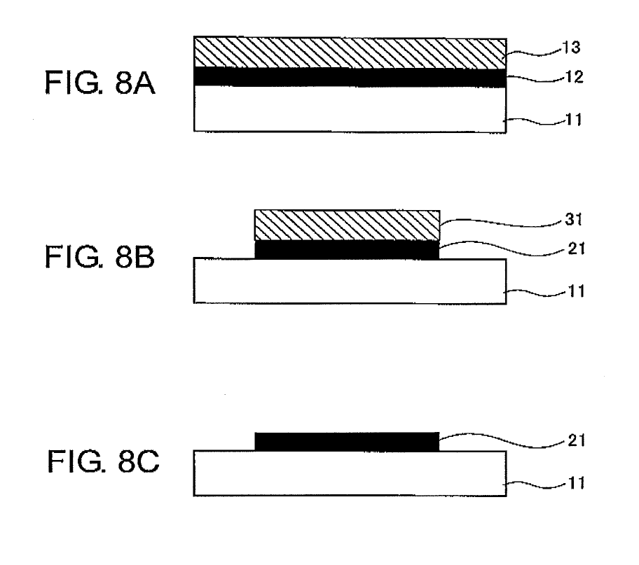

FIGS. 8A to 8C are schematic sectional views illustrating a manufacturing process of a trim mask.

As a transparent substrate 11 of the trim mask 2, use was made of a quartz glass substrate (having a size of 6 inch square and a thickness of 0.25 inch) having mirror-polished surfaces and subjected to predetermined cleaning.

At first, as shown in FIG. 8A, a light-shielding film 12 of chromium was deposited on the transparent substrate 11 to a thickness of 100 nm by sputtering. Then, a negative-type electron-beam resist (“SAL-601” manufactured by Shipley Corporation) 13 was applied to a thickness of 500 nm by spin coating.

Next, as shown in FIG. 8B, in order to form a light-transmitting portion, a desired pattern was drawn by electron-beam writing and then developed, thereby forming a resist pattern 31. Then, using the resist pattern 31 as a mask, the light-shielding film 12 was dry-etched with a mixed gas of Cl₂ and O₂, thereby obtaining a light-shielding film pattern 21 having designed dimensions.

Then, as shown in FIG. 8C, the resist was stripped, thereby forming a trim mask having the light-shielding film pattern 21.

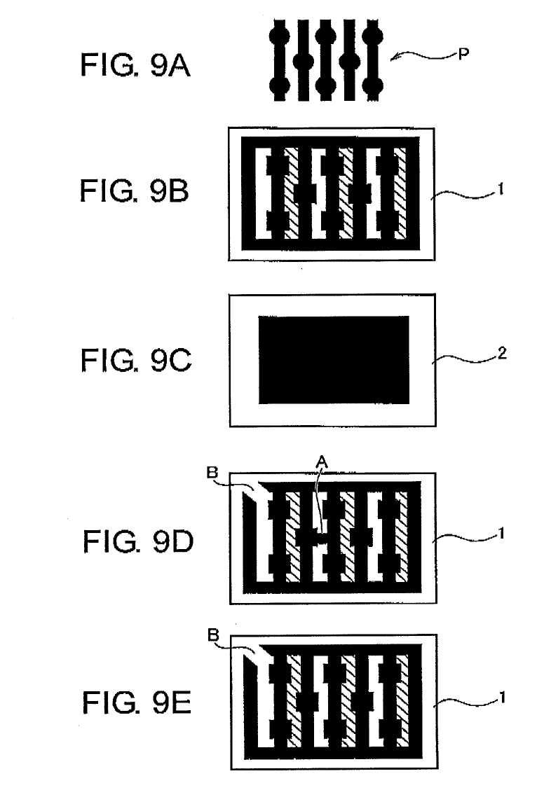

FIGS. 9A to 9E are plan views illustrating parts of patterns formed on photomasks and a wafer.

FIG. 9A illustrates a part of a pattern P to be obtained on the wafer using the above-mentioned photomasks. FIG. 9B shows a plan view (a part) of a phase shift mask 1. FIG. 9C shows a plan view (a part) of a trim mask 2.

Defect inspection of the completed phase shift mask 1 was performed. As a result, two defects were detected as shown in FIG. 9b. One of the defects is a residual defect A while the other defect is a missing defect B. At this stage, these defects were examined by superposing mask writing data of the phase shift mask 1 and the trim mask 2. As a result, it was easily found that the residual defect A was a defect contained in a main pattern and that, if this defect was left uncorrected, a bridge defect would be caused also on the wafer. On the other hand, it was found that the missing defect B was present within an area where the phase shift mask pattern would not be left on the wafer as a result of exposure using the trim mask 2 and therefore no influence would be given to the final result whether corrected or not. Accordingly, only the residual defect A was removed and corrected by a repair apparatus using laser light. As a result, as shown in FIG. 9E, the phase shift mask 1 with one missing defect was completed. Heretofore, such a phase shift mask is judged as a defective product. However, the phase shift mask is usable without any problem in practical use and, as shown in FIG. 9A, the desired pattern P was obtained.

In this example, description has been made of the phase shift mask having a single trench structure with an undercut formed by the use of dry etching and wet etching in combination. However, in this invention, no limitation is imposed on the mask structure as long as pattern formation using a trim mask is performed. For example, use may be made of a structure with no undercut or a dual trench structure. Further, without being limited to the Levenson-type phase shift mask, this invention is similarly applicable to any phase shift mask adapted for use in combination with a trim mask, for example, a chromeless-type phase shift mask.

On the other hand, as the trim mask, description has been made of a typical binary mask using Cr in the foregoing example. However, the trim mask may be a halftone-type phase shift mask. The type and the structure of the mask may be freely selected as desired.

In the foregoing example, this invention has been described in the case where this invention is applied to the combination of the phase shift mask and the trim mask. As described before, however, this invention is also applicable to the case where a fine pattern is formed by double exposure.

Herein, referring to FIGS. 10A to 10H, description will be made of a process of forming a fine pattern by double exposure.

At first, as shown in FIG. 10A, a photomask blank is prepared in which, on a semiconductor substrate 41, an underlayer film 42, a hard mask (for example, a silicon nitride film) 43 having a thickness of about 0.1 μm, and finally, a positive resist film 44 for ArF exposure having a thickness of about 0.15 μm are formed. In this example, a fine pattern is formed on the photomask blank by double exposure.

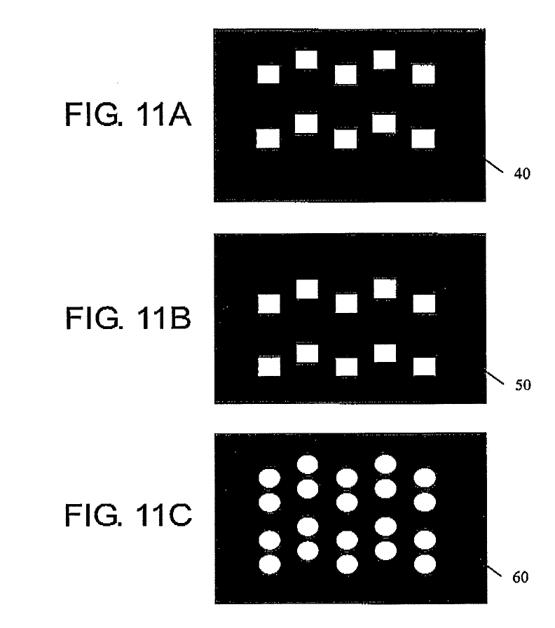

Then, first exposure is performed using ArF excimer laser light, for example, through a first photomask as shown in FIG. 11A, thereby forming exposed portions 44a in the positive resist film 44 (FIG. 10B).

Subsequently, second exposure is performed using ArF excimer laser light, for example, through a second photomask as shown in FIG. 11B, thereby forming exposed portions 44b in the positive resist film 44 (FIG. 10C).

After the exposure, the ArF resist film 44 is baked using a hot plate and then developed, thereby forming a resist pattern 441 (FIG. 10D).

Then, using the resist pattern 441 as a mask, the hard mask 43 is etched with a fluorine-based gas, thereby forming a hard mask pattern 431 (FIG. 10E).

Then, the resist pattern 441 is removed by oxygen plasma ashing and the patterning of the hard mask is finished (FIG. 10F).

By the resist exposure performed twice as described above, a fine hard mask pattern 432 is obtained and, using the hard mask pattern 432, the underlayer film 42 formed on the semiconductor substrate is dry-etched (FIG. 10G). Finally, the hard mask pattern 432 is removed, so that fine processing of the underlayer film is achieved (FIG. 10H).

In the practical application, a pattern to be transferred onto a thin film (the underlayer film 42 described above) is divided into two characteristic patterns. These patterns are respectively formed on different masks. Exposure conditions for the respective masks are determined to be suitable for the respective characteristic patterns. These patterns are successively transferred onto the same object by exposure. Since the different exposure conditions can be applied to the respective characteristic patterns, it is possible to increase an apparent resolution. For example, in the case where line patterns and hole patterns are mixed in a pattern to be transferred, the line patterns and the hole patterns are separately formed on different masks. By applying different exposure conditions (mainly, off-axis illumination or modified illumination can be used) to the respective masks, those patterns of the respective masks are transferred onto the same object, thereby forming a single resist pattern on the object.

This invention is advantageously applicable also to the above-mentioned case, as shown in another example which will be described later.

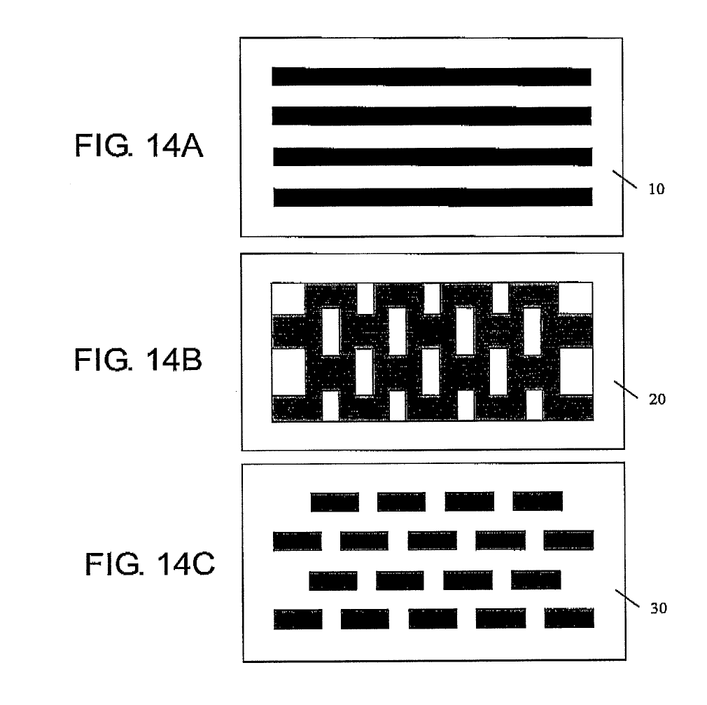

In the above-mentioned example, description has been made of the case where the fine pattern is formed by double exposure. Furthermore, as shown in FIGS. 13A to 13L and 14A to 14C, this invention is similarly applicable to the case where a fine pattern is formed by double patterning.

When double patterning is performed, an underlayer film 52, a hard mask (for example, a silicon nitride film) 53 having a thickness of about 0.1 μm, and finally, a first positive resist film 54 for ArF exposure having a thickness of about 0.15 μm are formed on a semiconductor substrate 51, as shown in FIG. 13A.

Then, first exposure is performed using ArF excimer laser light, for example, through a first photomask as shown in FIG. 14A, thereby forming exposed portions 54a (FIG. 13B).

After the exposure, the first ArF resist film 54 is baked using a hot plate and then developed, thereby forming a first resist pattern 541 (FIG. 13C).

Then, using the first resist pattern 541 as a mask, the hard mask 53 is etched with a fluorine-based gas, thereby forming a first hard mask pattern 531 (FIG. 13D).

Then, the first resist pattern 541 is removed by oxygen plasma ashing and the first-stage patterning is finished (FIG. 13E).

Next, a second ArF resist film 55 having a thickness of about 0.15 μm is formed on the first hard mask pattern 531 (FIG. 13F).

Then, second exposure is performed using ArF excimer laser light, for example, through a second photomask as shown in FIG. 14B, thereby forming exposed portions 55a (FIG. 13G).

After the exposure, the second ArF resist film 55 is baked using the hot plate and then developed, thereby forming a second resist pattern 551 (FIG. 13H).

Then, using the second resist pattern 551 as a mask, the hard mask 532 is etched using a fluorine-based gas (FIG. 13I).

Then, the second resist pattern 551 is removed by oxygen plasma ashing so that the second-stage patterning is finished (in FIG. 13J).

By the resist exposure and the hard mask etching each performed twice as described above, the fine second hard mask pattern 532 is obtained and, using the second hard mask pattern 532, the underlayer film 52 formed on the semiconductor substrate is dry-etched (FIG. 13K). Finally, the second hard mask pattern 532 is removed, so that fine processing of the underlayer film can be achieved (FIG. 13L).

In the double patterning, for example, when a line-and-space pattern is formed, the pattern may be divided every other line into two masks. Also in this case, it is possible to increase an apparent resolution. These masks are used for transferring an ultrafine pattern such as a 45 nm or 32 nm half-pitch pattern.

Also in this case, an excellent effect is obtained by applying this invention as shown in another example which will be described later.

### Example 2

Description will be made of Example 2 where this invention is applied to double patterning.

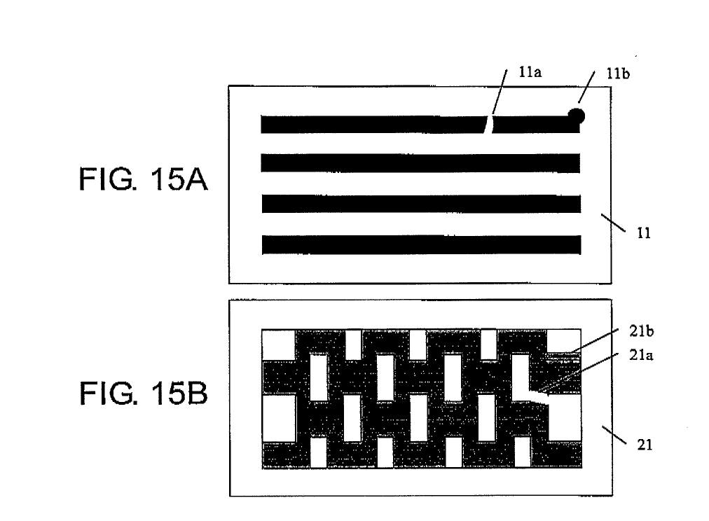

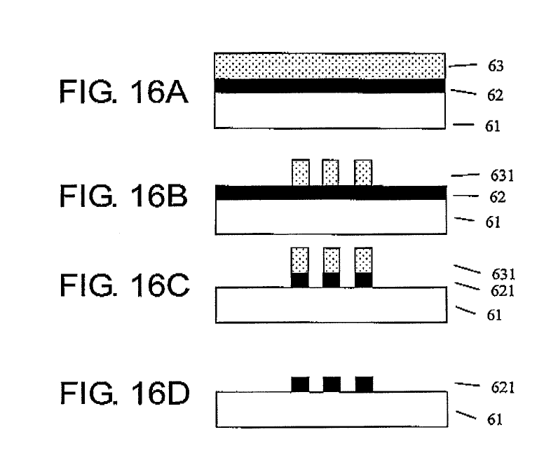

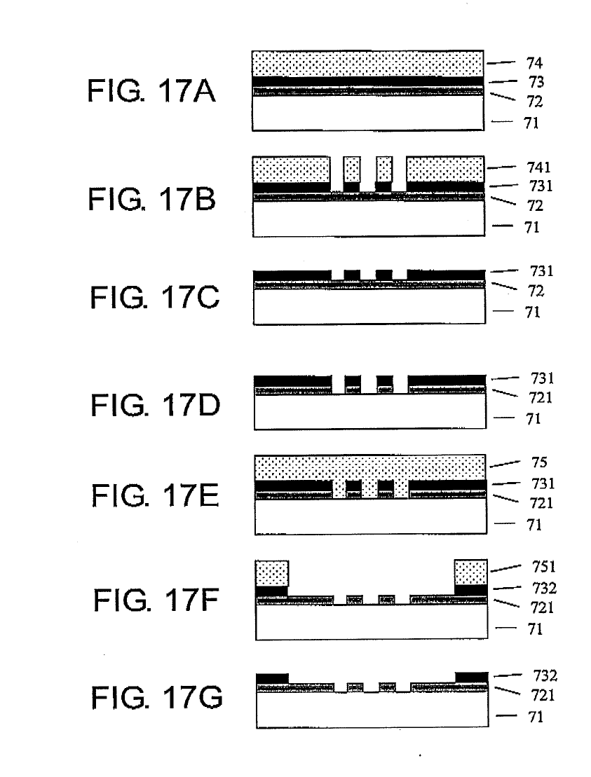

First, FIGS. 16A to 16D and 17A to 17G are schematic sectional views illustrating a manufacturing process of two photomasks according to the example of this invention. FIGS. 15A and 15B illustrate generated defects detected as a result of defect inspection of the two masks. The example of this invention will be described with reference to these figures.

In order to perform patterning on a wafer as shown in FIG. 14C through the double patterning process shown in FIGS. 13A to 13L, two photomasks 10 and 20 as shown in FIGS. 14A and 14B were manufactured.

The manufacturing process of the photomask 10 shown in FIG. 14A will be described with reference to FIGS. 16A to 16D.

A transparent substrate 61 is a quartz glass substrate (having a size of 6 inch square and a thickness of 0.25 inch) having mirror-polished surfaces and subjected to predetermined cleaning. At first, a light-shielding film 62 of chromium was formed on the transparent substrate 61 to a thickness of 100 nm by sputtering. Then, a negative-type electron-beam resist (“SAL-601” manufactured by Shipley Corporation) 63 was applied to a thickness of 500 nm by spin coating (FIG. 16A).

Then, in order to form a chromium pattern, a desired pattern was drawn by electron-beam writing and then developed, thereby forming a resist pattern 631 (FIG. 16B).

Then, using the resist pattern 631 as a mask, the light-shielding film 62 was dry-etched with a mixed gas of Cl₂ and O₂, thereby obtaining a light-shielding film pattern 621 having designed dimensions (FIG. 16C).

Finally, the resist was stripped, thereby completing a photomask having the light-shielding film pattern 621 (FIG. 16D).

The manufacturing process of the photomask 20 shown in FIG. 14B will be described with reference to FIGS. 17A to 17G.

A transparent substrate 71 is a quartz glass substrate (having a size of 6 inch square and a thickness of 0.25 inch) having mirror-polished surfaces and subjected to predetermined cleaning. At first, a light-semitransmitting film 72 of molybdenum silicide was formed on the transparent substrate 71 to a thickness of 68 nm by sputtering. Subsequently, a light-shielding film 73 of chromium was formed to a thickness of 60 nm by sputtering. Then, a positive-type electron-beam resist (“ZEP7000” manufactured by Zeon Corporation) 74 was applied to a thickness of 300 nm by spin coating (FIG. 17A).

Then, an aperture pattern was drawn using an electron-beam writing apparatus and then developed, thereby forming a first resist pattern 741. Then, using the first resist pattern 741 as a mask, the light-shielding film was dry-etched with a mixed gas of Cl₂ and O₂, thereby forming a light-shielding film pattern 731 (FIG. 17B).

Thereafter, the remaining first resist pattern 741 was stripped and cleaning was carried out (FIG. 17C).

Then, using the light-shielding film pattern 731 obtained by the above-mentioned steps as a mask, the light-semitransmitting film 72 was dry-etched with a mixed gas of CF₄ and O₂, thereby forming a light-semitransmitting film pattern 721 (FIG. 17D).

Then, a positive-type electron-beam resist (“ZEP7000” manufactured by Zeon Corporation) 75 was formed as a second resist film on a substrate surface obtained by the above-mentioned steps (FIG. 17E).

Then, a region corresponding to a main aperture portion was drawn on the second resist film using the writing apparatus and then developed, thereby forming a second resist pattern 751. Then, using the resist pattern 751 as a mask, the light-shielding film was dry-etched with a mixed gas of Cl₂ and O₂, thereby forming a light-shielding film pattern 732 (FIG. 17F).

Thereafter, the remaining second resist pattern 751 was stripped, thereby completing a halftone-type phase shift mask (FIG. 17G).

Defect inspection of the completed two photomasks was performed. As a result, two defects were detected in the first mask as shown in FIG. 15A. One of the defects is a missing defect 11a while the other defect is a residual defect 11b. At this stage, these defects were examined by superposing mask writing data of the first mask and the second mask. As a result, it was found that the missing defect 11a was a pattern defect which was contained in a region that would be exposed by the second mask and which would not be formed finally and, therefore, which need not be corrected. It was also found that the residual defect 11b was also located in a region that would be exposed by the second mask and, therefore, need not be corrected.

In the second mask, two defects were detected as shown in FIG. 15B. One of the defects is a missing defect 21a while the other defect is a residual defect 21b. At this stage, these defects were examined by superposing mask writing data of the first mask and the second mask. As a result, it was found that the missing defect 21a need not be corrected because this defect was located at a position where the first mask has no pattern and, even if exposed, no problem would be caused and thus this defect is contained in a pattern portion which would not be formed finally. It was also found that the residual defect 21b need not be corrected also because this defect was located at a position where the first mask has no pattern and therefore exposure need not be performed and thus this defect would not affect a final pattern.

As a single independent mask, each of the masks with two defects as shown in FIGS. 15A and 15B must be corrected because of presence of the defects and, depending on the case, will be rejected as a defective product. However, when the first and the second masks are combined, these masks are usable without any problem in practical use. A desired pattern was obtained on a wafer by combining the first and the second masks.

### Example 3

Description will be made of Example 3 where this invention is applied to double exposure.

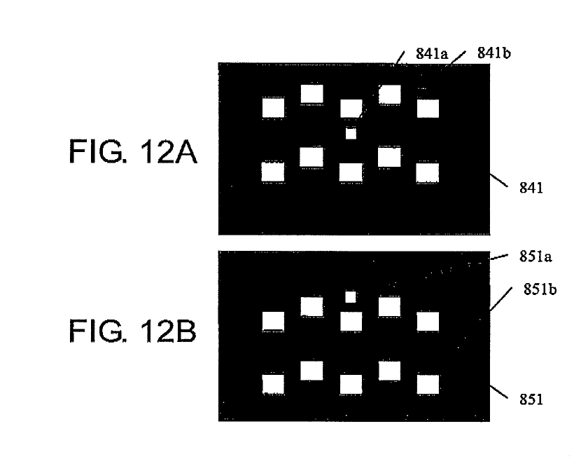

Schematic sectional views of a manufacturing process of two photomasks according to the example of this invention are similar to FIGS. 17A to 17G and, therefore, are omitted herein. FIGS. 12A and 12B illustrate generated defects detected as a result of defect inspection of the two masks. The example of this invention will be described with reference to these figures.

In order to perform patterning on a wafer as shown in FIG. 11C through the double exposure process shown in FIGS. 10A to 10H, two photomasks as shown in FIGS. 11A and 11B were manufactured. The manufacturing process of these photomasks is similar to that shown in FIGS. 17A to 17G.

Defect inspection of the completed two photomasks was performed. As a result, two defects were detected in the first mask as shown in FIG. 12A. One of the defects is a missing defect 841a while the other defect is a Cr residual defect 841b. At this stage, these defects were examined by superposing mask writing data of the first mask and the second mask. As a result, it was found that the missing defect 841a need not be corrected because the missing defect was located at a position that would be exposed by the second mask. It was also found that the residual defect 841b need not be corrected because the residual defect was located at a position where the pattern was not exposed in the second mask.

In the second mask, two defects were detected as shown in FIG. 12B. One of the defects is a missing defect 851a while the other defect is a residual defect 851b. At this stage, these defects were examined by superposing mask writing data of the first mask and the second mask. As a result, it was found that these defects need not be corrected for the reasons quite same as those in the first mask.

As result, each of the masks with two defects as shown in FIGS. 12A and 12B was completed. As a single independent mask, correction is required. Depending on the case, these masks are rejected as defective products. In practical use, however, these masks are usable without any problem. A desired pattern shown in FIG. 11C was obtained on a wafer by combining the first and second masks.

As described above, the photomask defect correction method according to this invention is widely applicable to various types of masks adapted to form a pattern using a plurality of masks.

What is claimed is:

1. A defect correction method for a photomask, said photomask having a first transfer pattern to be transferred onto an object, said photomask being adapted to be used in combination with a second photomask having a second transfer pattern to be transferred onto said object, wherein:
a pattern defect which is produced in said first transfer pattern is corrected only if said pattern defect is to be transferred onto said object within a region which is out of an area where a pattern corresponding to said first transfer pattern is not formed on said object as a result of transferring said second transfer pattern onto said object.

2. The defect correction method according to claim 1, wherein said first transfer pattern includes a phase shift pattern having a trench formed on a transparent substrate.

3. The defect correction method according to claim 1, wherein one of said first and said second transfer patterns is adapted to erase an unwanted pattern formed on said object by the other of said first and said second transfer patterns.

4. The defect correction method according to claim 1, wherein said first and said second transfer patterns are designed so that transferring one of said first and said second transfer patterns onto said object increases an apparent resolution when the other of said first and said second transfer patterns is transferred onto said object.

5. The defect correction method according to claim 1, wherein said first photomask and said second photomask are transferred onto said object under different exposure conditions.

6. The defect correction method according to claim 1, wherein said first and said second transfer patterns are obtained by dividing a pattern which is to be formed on said object and which exceeds a resolution limit of an exposure apparatus into two parts each within the resolution limit of said exposure apparatus.

7. A photomask manufacturing method comprising a defect correction process according to the defect correction method according to claim 1.

8. A method of manufacturing a phase shift mask comprising a transparent substrate on which a light-shielding layer and a shifter layer each subjected to predetermined patterning are formed so that said phase shift mask has a phase shift mask pattern including a phase-unshifted light-transmitting portion, a phase shift portion, and a light-shielding portion, said phase shift portion being adapted to transmit exposure light with a phase shift of substantially 180° relative to unshifted exposure light transmitted through said phase-unshifted light-transmitting portion, said method comprising:
a defect correction process of performing defect correction of said phase shift mask pattern formed after the patterning of said light-shielding layer and said shifter layer,
said defect correction process including:
identifying a position of a pattern defect in said phase shift mask pattern;
referring to data of a trim mask pattern formed on a trim mask to be transferred onto an object before or after said phase shift mask pattern is transferred onto said object using said phase shift mask; and
correcting the position-identified pattern defect only if said pattern defect is to be transferred onto said object within a region which is out of an area where a pattern corresponding to said phase shift mask pattern is not formed on said object as a result of transferring said trim mask pattern onto said object.

9. A photomask having a first transfer pattern to be transferred onto an object, said photomask being adapted to be used in combination with a second photomask having a second transfer pattern to be transferred onto said object, wherein:
a pattern defect which is produced in said first transfer pattern is corrected only if said pattern defect is to be transferred onto said object within a region which is out of an area where a pattern corresponding to said first transfer pattern is not formed on said object as a result of transferring said second transfer pattern onto said object.

10. A phase shift mask having a phase shift mask pattern to be transferred onto an object and including a phase shift portion, said phase shift mask being adapted to be used in combination with a second mask having a second transfer pattern to be transferred onto said object, wherein:
a pattern defect which is produced in said phase shift mask pattern is corrected only if said pattern defect is to be transferred onto said object within a region which is out of an area where a pattern corresponding to said phase shift pattern is not formed on said object as a result of transferring said second transfer pattern onto said object using said second mask.

11. A photomask set comprising a phase shift mask and a trim mask, said phase shift mask having a phase shift mask pattern to be transferred onto an object and including a phase shift portion, said trim mask having a trim mask pattern to be transferred onto said object before or after said phase shift mask pattern is transferred onto said object using said phase shift mask, wherein:
said phase shift mask is subjected to defect correction only for a region except a trim region, said trim region being an area contained within a range of said phase shift mask pattern and overlapping a light-transmitting portion of said trim mask pattern when said phase shift mask pattern and said trim mask pattern are superposed on each other.

12. A pattern transfer method comprising transferring a pattern onto an object using a photomask manufactured by the method according to claim 7.

13. A pattern transfer method comprising transferring a pattern onto an object using a phase shift mask manufactured by the method according to claim 8.

14. A pattern transfer method comprising transferring a pattern onto an object using the photomask according to claim 9.

15. A pattern transfer method comprising transferring a pattern onto an object using the phase shift mask according to claim 10.
